(19) United States
(12) Patent Application Publication
(10) Pub. No.: US 2025/0096157 A1
(43) Pub. Date: Mar. 20, 2025

(54) SEMICONDUCTOR PACKAGE

(71) Applicant: SAMSUNG ELECTRONICS CO., LTD., SUWON-SI (KR)

(72) Inventor: Kangjoon Lee, Suwon-si (KR)

(21) Appl. No.: 18/651,891

(22) Filed: May 1, 2024

(30) Foreign Application Priority Data
Sep. 14, 2023 (KR) 10-2023-0122668

(51) Int. Cl. H01L 23/00; H01L 23/498; H01L 25/16

(52) U.S. Cl. CPC H01L 23/562; H01L 23/49816; H01L 23/49838; H01L 25/16

(57) ABSTRACT

A semiconductor package includes a package substrate, a package body disposed on an upper surface of the package substrate, and a stiffener disposed at each of four sides of the package substrate, wherein the stiffener includes a horizontal part covering the upper surface of the package substrate at the four sides of the package substrate and a vertical part extending downward from the horizontal part in a vertical direction substantially perpendicular to the upper surface of the package substrate at four corners of the package substrate, and the vertical part protrudes in the vertical direction from a lower surface of the package substrate.

### CROSS-REFERENCE TO RELATED APPLICATION

This application is based on and claims priority under 35 U.S.C. § 119 to Korean Patent Application No. 10-2023-0122668, filed on Sep. 14, 2023, in the Korean Intellectual Property Office, the disclosure of which is incorporated by reference herein in its entirety.

### TECHNICAL FIELD

The inventive concept relates to a semiconductor package, and more particularly, to a semiconductor package including a stiffener.

### DESCRIPTION OF RELATED ART

Demand for high performance, high speed, and miniaturized electronic products is increasing. A structure where a plurality of semiconductor chips are stacked on a package substrate or a structure where a package is stacked on another package has been proposed to satisfy these demands. The semiconductor packages may be implemented with different structures, including for example, a package-in-package (PIP), a package-on-package (POP), or a system-in-package (SIP).

The semiconductor packages may be mounted on a board of an electronic device such as a mobile device or an external system. The board may warp during a manufacturing process. Warpage of the board may lead to significant problems, which may decrease a reliability of the electronic device.

### SUMMARY

The inventive concept provides a semiconductor package which may increase device reliability by reducing warpage of a board with the semiconductor package mounted thereon. The objects of the inventive concept are not limited, and other objects not described herein will be clearly understood by those of ordinary skill in the art from descriptions herein.

According to an aspect of the inventive concept, there is provided a semiconductor package including a package substrate, a package body disposed on an upper surface of the package substrate, and a stiffener disposed at sides of the package substrate, wherein the stiffener includes a horizontal part disposed on the upper surface of the package substrate at the sides of the package substrate and a vertical part extending downward from the horizontal part in a vertical direction substantially perpendicular to the upper surface of the package substrate at corners of the package substrate, and the vertical part protrudes in the vertical direction from a lower surface of the package substrate.

According to another aspect of the inventive concept, there is provided a semiconductor package including a package substrate having a tetragonal shape, a package body disposed on an upper surface of the package substrate, a stiffener disposed at sides of the package substrate, and an external connection terminal disposed on a lower surface of the package substrate, wherein a first side and a third side of the package substrate are opposite to each other and extend in a first direction parallel to the upper surface of the package substrate, a second side and a fourth side of the package substrate are opposite to each other and perpendicular to the first direction and extend in a second direction parallel to the upper surface of the package substrate, the stiffener includes a horizontal part disposed on the upper surface of the package substrate at the sides of the package substrate and a plurality of vertical parts extending downward from the horizontal part in a vertical direction perpendicular to the upper surface of the package substrate at corners of the package substrate formed by the first side, the second side, the third side, and the fourth side, and the plurality of vertical parts protrude from the lower surface of the package substrate in the vertical direction and a protrusion length of the plurality of vertical parts has a range of about 39% to about 43% of a height of the external connection terminal with respect to the lower surface of the package substrate.

According to another aspect of the inventive concept, there is provided a semiconductor package including an external board, a package substrate disposed on the external board and having a tetragonal shape including four sides, a package body disposed at a center portion of an upper surface of the package substrate, a stiffener disposed between the four sides of the package substrate, and an external connection terminal disposed between a lower surface of the package substrate and the external board, wherein a first side and a third side of the four sides of the package substrate are opposite to each other and extend in a first direction parallel to the upper surface of the package substrate, a second side and a fourth side of the four sides of the package substrate are opposite to each other and perpendicular to the first direction and extend in a second direction parallel to the upper surface of the package substrate, the stiffener includes a horizontal part disposed on the upper surface of the package substrate at the four sides of the package substrate and a vertical part extending downward from the horizontal part in a vertical direction perpendicular to the upper surface of the package substrate at four corners of the package substrate, the external board has a warpage shape where a center portion is disposed away from the package substrate in the first direction, and the vertical part protrudes by a first length in the vertical direction from a lower surface of the package substrate and contacts an upper surface of the external board in the first direction.

### BRIEF DESCRIPTION OF THE DRAWINGS

Embodiments will be more clearly understood from the following detailed description taken in conjunction with the accompanying drawings in which:

FIGS. 1A, 1B, and 1C are a plan view, a cross-sectional view, and an enlarged view of a semiconductor package according to an embodiment;

FIGS. 2A, 2B, and 2C are a plan view and cross-sectional views of a semiconductor package according to an embodiment;

FIGS. 3A and 3B are cross-sectional views of a semiconductor package of a comparative example and the semiconductor package of FIG. 2A;

FIGS. 4A, 4B, and 4C are plan views of a semiconductor package according to some embodiments;

FIGS. 5A and 5B are cross-sectional views illustrating a package body portion in the semiconductor package of FIG. 1B;

FIGS. 6A and 6B are cross-sectional views illustrating the package body portion in the semiconductor package of FIG. 1B; and

FIGS. 7A to 7D are cross-sectional views simply illustrating a method of manufacturing a semiconductor package, according to an embodiment.

### DETAILED DESCRIPTION

The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Hereinafter, embodiments will be described in detail with reference to the accompanying drawings. Like reference numerals refer to like elements in the drawings, and their repeated descriptions may be omitted.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concepts. The singular forms include the plural forms unless the context clearly indicates otherwise.

Terms such as “below”, “lower”, “above”, “upper” or the like, may be used in the description to describe one element's relationship to another element illustrated in the figures. It will be understood that the terms have a relative concept and may be described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

The following will now describe a semiconductor package, and more specifically, to a semiconductor package including a stiffener.

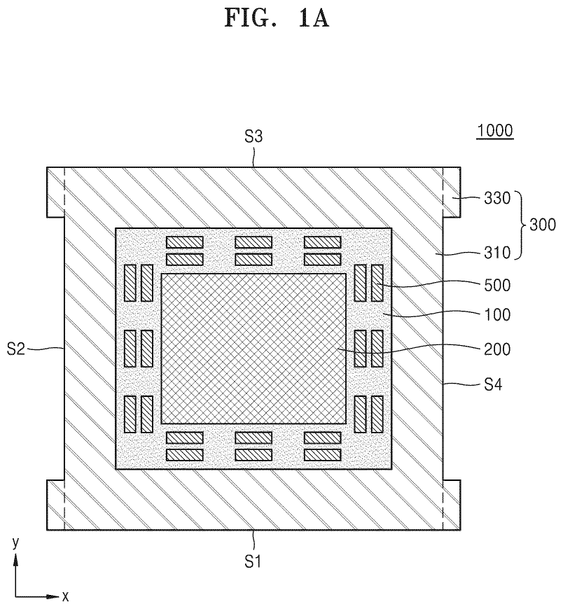

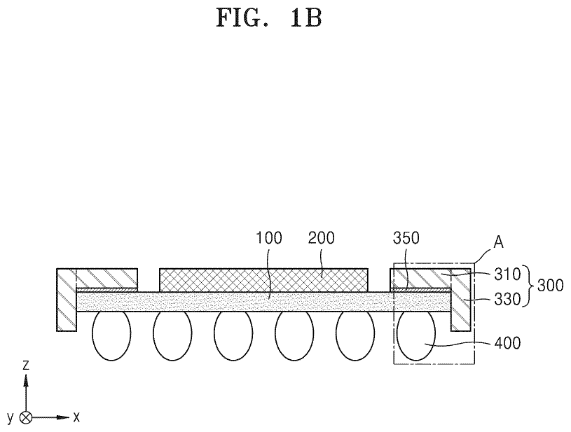

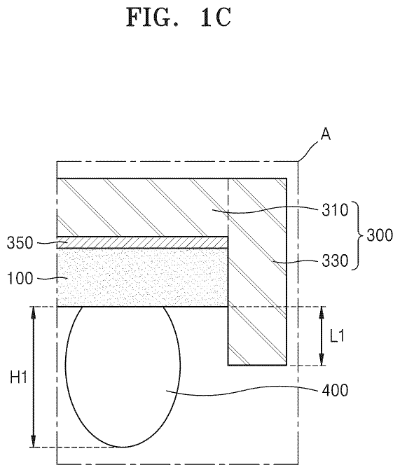

FIG. 1A is a plan view of a semiconductor package 1000 according to an embodiment. FIG. 1B is a cross-sectional view of the semiconductor package 1000 according to an embodiment. FIG. 1C is an enlarged view of the semiconductor package 1000 according to an embodiment. More particularly, FIG. 1C is an enlarged view of a region A of FIG. 1B.

Referring to FIGS. 1A, 1B, and 1C, the semiconductor package 1000 according to an embodiment may include a package substrate 100, a package body 200, a stiffener 300, an external connection terminal 400, and a passive device 500.

The package substrate 100 may include, for example, a core layer, a wiring layer, and a protection layer. The core layer may include, for example, resin and glass fiber such as frame retardant 4 (FR-4). A material of the core layer is not limited thereto. For example, the core layer may include bismaleimide triazine (BT) resin, polycarbonate (PC) resin, a build-up film such as an AJINOMOTO BUILD-UP FILM® (ABF), or laminate resin. The core layer may have a relatively thin thickness as compared to the wiring layer and the protection layer. For example, the core layer may have a thickness of about 40 μm to about 20 μm. According to an embodiment, a thickness of the core layer is not limited to the numerical range above.

The wiring layer may be disposed on the core layer and under the core layer. A portion of wiring layer disposed on the core layer may be an upper wiring layer. A portion of wiring layer disposed under the core layer may be a lower wiring layer. The wiring layer may include multiple wiring lines. The wiring lines may be layered in a stack-up. For example, a number of layers of the wiring lines of the upper wiring layer may be the same as or different from the number of layers of the wiring lines of the lower wiring layer.

In the semiconductor package 1000 according to an embodiment, the wiring layer may include, for example, an 8-layer stack-up or a 14-layer stack-up. The number of layers of the wiring lines of the wiring layer is not limited thereto. A thickness of the wiring layer may be changed based on the number of layers of the wiring lines. A thickness of the wiring layer may be, for example, about 100 μm to about 1,000 μm. A thickness of the wiring layer is not limited to this numerical range.

The wiring layer may include a metal wiring corresponding to each of the wiring lines, an interlayer insulation layer which insulates the wiring lines, and a metal via which connects wiring lines of different layers with each other. The metal wiring and the metal via may include, for example, copper (Cu). The material(s) of the metal wiring and the metal via are not limited to Cu. The interlayer insulation layer may include, for example, polypropylene glycol (PPG). A material of the interlayer insulation layer is not limited to PPG.

The protection layer may protect the core layer and the wiring layer from external damage, for example, physical and/or chemical damage. The protection layer may include, for example, solder resist (SR). The protection layer may include an upper protection layer on an upper surface of the upper wiring layer and a lower protection layer on a lower surface of the lower wiring layer. For example, a package substrate 100 may include the upper protection layer, the upper wiring layer, the core layer, the lower wiring layer, and the lower protection layer, sequentially disposed.

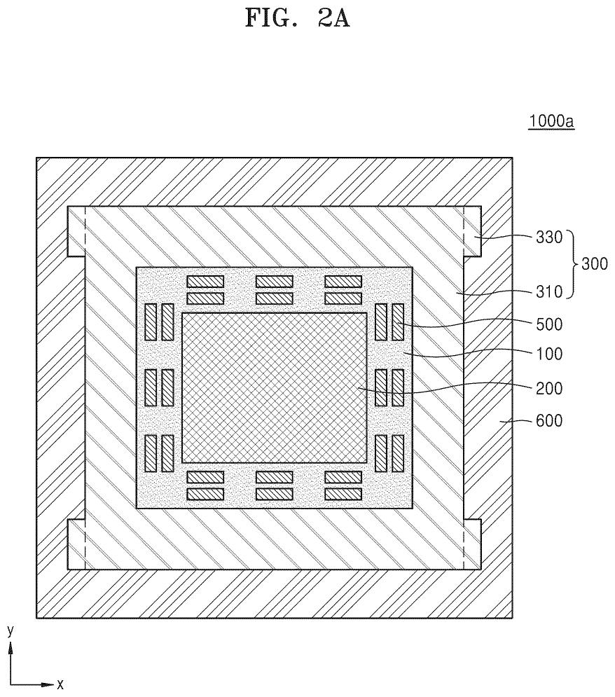

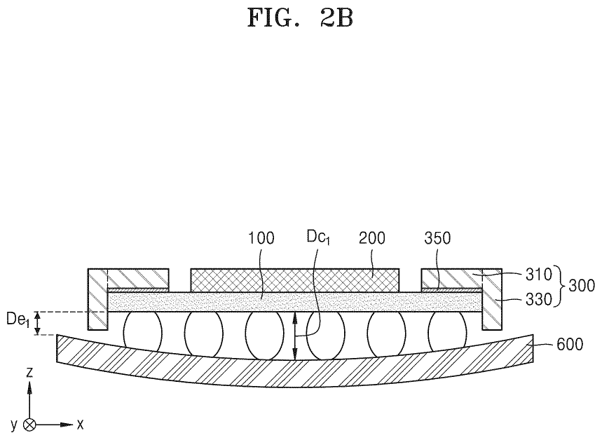

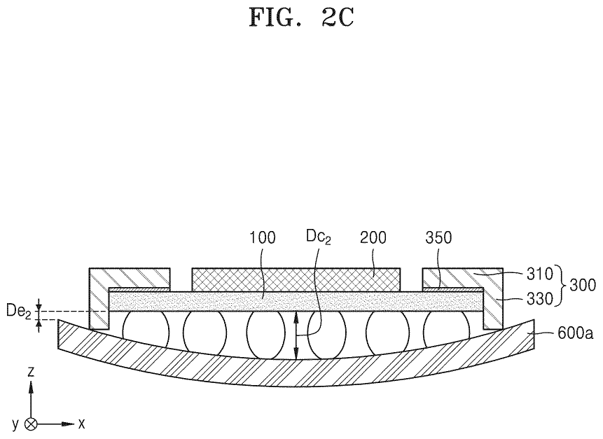

Furthermore, the package substrate 100 may be, for example, a printed circuit board (PCB). The package substrate 100 is not limited to the PCB. For example, the package substrate 100 may include a glass substrate, an organic substrate, or a redistribution substrate. The semiconductor package 1000 may be disposed on a package substrate 100 of an external system or a board (see board 600 of FIG. 2A) of an electronic device, such as a mobile device, through the external connection terminal 400 disposed on a lower surface of the package substrate 100. For reference, in the semiconductor package 1000 according to an embodiment, the size of the package substrate 100 may be less than or equal to about 50*50 mm². Here, a size may denote a flat area of the package substrate 100. The size of the package substrate 100 is not limited to this numerical example, and the size of the package substrate 100 may be varied.

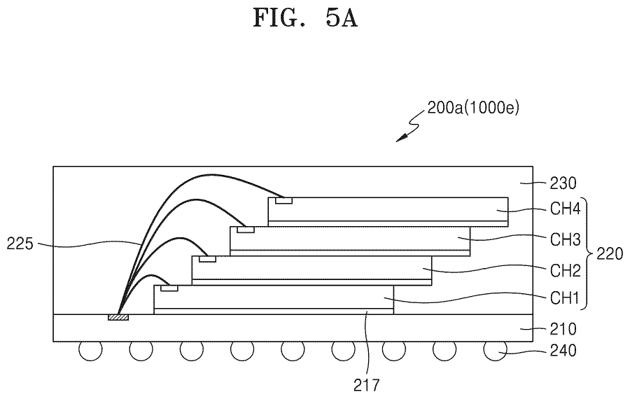

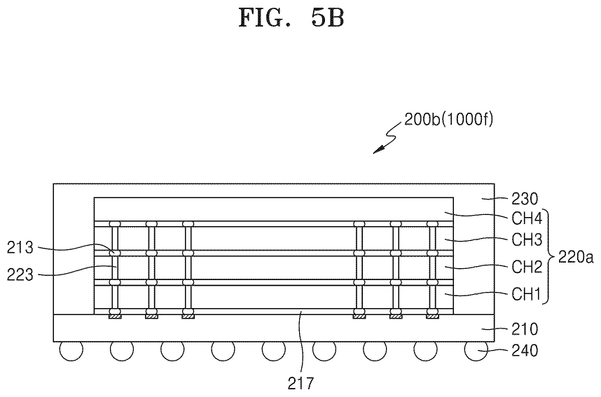

The package body 200 may be disposed on the package substrate 100. For example, the package body 200 may be mounted on the package substrate 100 as a flip chip type by using a body connection terminal (see body connection terminal 240 of FIG. 5A). The body connection terminal may differ in size and may include substantially the same material as the external connection terminal 400 described herein. The body connection terminal may be referred to as a bump. As illustrated in FIG. 1A, the package body 200 may be disposed at a center portion of the package substrate 100.

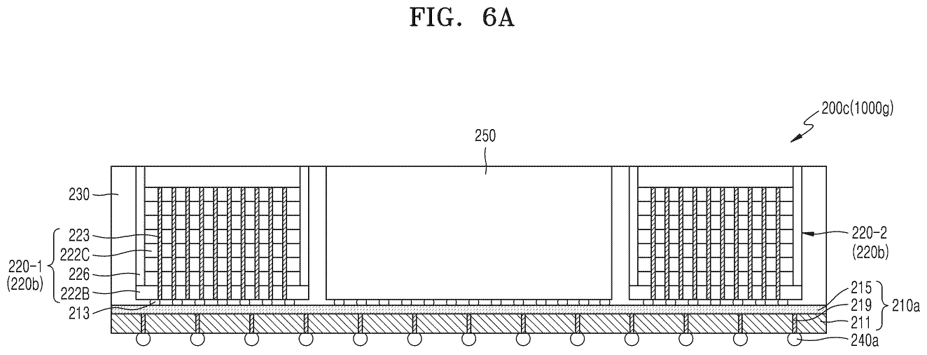

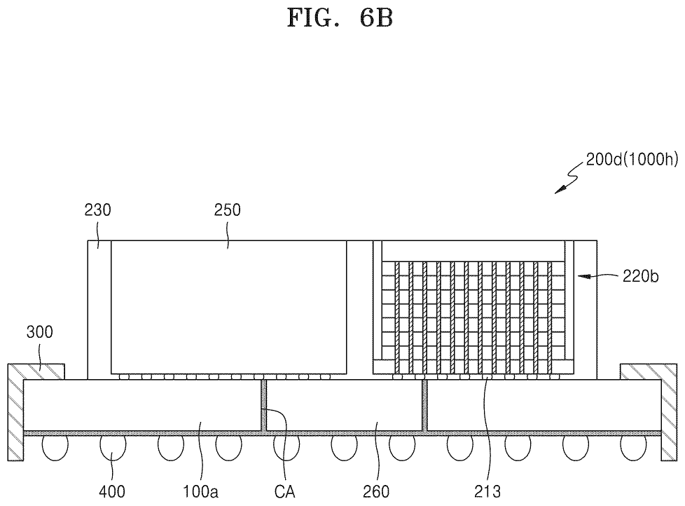

The package body 200 may include a single semiconductor chip. The package body 200 is not limited thereto and may include a chip stack portion having a structure where a plurality of semiconductor chips are stacked. A structure where a package body includes a chip stack portion will be described herein in more detail with reference to FIGS. 5A and 5B, and FIGS. 6A and 6B.

A semiconductor chip of the package body 200 may be, for example, a system on chip (SoC) or a logic chip. Here, the logic chip may include an application processor (AP), a microprocessor, a central processing unit (CPU), a controller, or an application specific integrated circuit (ASIC). In the semiconductor package 1000 according to an embodiment, the semiconductor chip of the package body 200 may be an SoC and may include at least two of a logic circuit, a memory circuit, a digital integrated circuit (IC), a radio frequency integrated circuit (RFIC), and an input/output circuit. The semiconductor chip of the package body 200 may be an SoC for an advanced RISC machine (ARM) server and may include a dynamic random access memory interface (DRAM I/F) for a dual in-line memory module (DIMM), a peripheral component interconnect express (PCIe) I/F having a switch function, and a CPU.

The stiffener 300 may be disposed on the package substrate 100 in a shape which surrounds an outer portion of the package substrate 100. The stiffener 300 may mechanically support the package substrate 100, and may thus improve a thermal characteristic of the package substrate 100 (for example, a warpage characteristic of the package substrate 100).

In the semiconductor package 1000 according to an embodiment, the stiffener 300 may include a horizontal part 310 and a vertical part 330. The horizontal part 310 may cover upper surfaces of four side portions of the package substrate 100 having a tetragonal shape. For example, the horizontal part 310 may have a tetragonal ring shape surrounding an outer portion of an upper surface of the package substrate 100. Therefore, when four sides of the package substrate 100 are divided into a first side S1, a second side S2, a third side S3, and a fourth side S4 in a clockwise direction, the horizontal part 310 may have a shape which extends in an x direction at the first side S1 and the third side S3 of the package substrate 100 and may cover the upper surface of the package substrate 100, and moreover, may have a shape which extends in a y direction at the second side S2 and the fourth side S4 of the package substrate 100 and may cover the upper surface of the package substrate 100. Here, the x direction and the y direction may be parallel to the upper surface of the package substrate 100. Furthermore, a side surface of the horizontal part 310 may substantially configure a coplanar surface with a side surface of the package substrate 100 of a corresponding side.

In some embodiments, the sides of the package substrate 100 may for corners therebetween. For example, the first side S1 and the second side S2 may form a first corner, the second side S2 and the third side S3 may form a second corner, the third side S3 and the fourth side S4 may form a third corner, and the fourth side S4 and the first side S1 may form a first corner.

The vertical part 330 may have a shape which extends downward in a z direction from the horizontal part 310. Here, the z direction may be perpendicular to the upper surface of the package substrate 100. The vertical part 330, as illustrated in FIG. 1A, may be disposed at end portions in the y direction, for example, at each of the second side S2 and the fourth side S4. Therefore, the vertical part 330 may be disposed at four positions. The vertical part 330 may be disposed at a portion corresponding to end portions of the package substrate 100 in the x direction. Here, the x direction may be a direction in which warpage occurs in a board (see board 600 of FIG. 2A) with the semiconductor package 1000 disposed thereon. Warpage of the board will be described herein in more detail with reference to FIGS. 2A, 2B, and 2C.

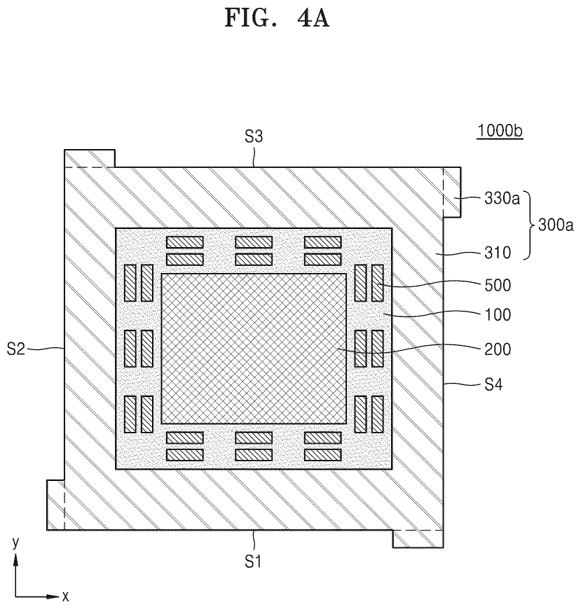

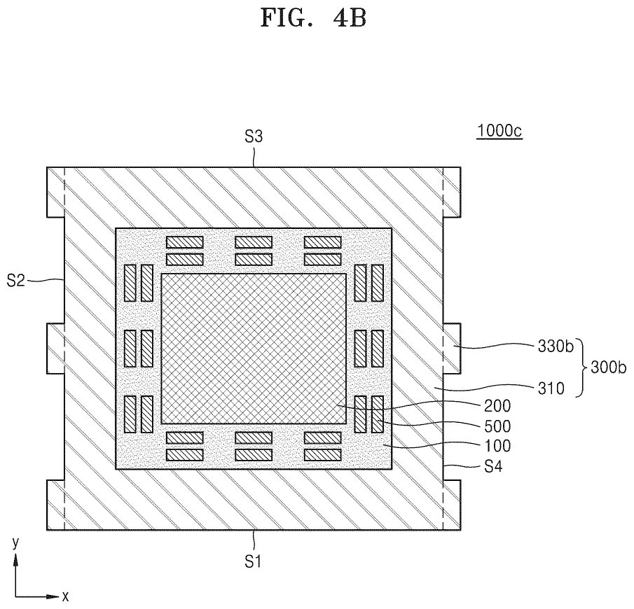

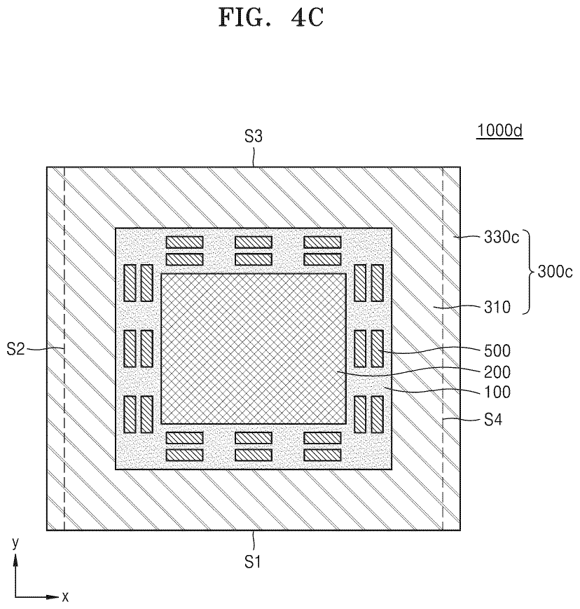

The vertical part 330, as illustrated in FIG. 1A, may be disposed at corner positions of the package substrate 100, formed by the first side S1 to the fourth side S4. Portions of the vertical part 330 disposed at the corner portions may be include an edge portion disposed coplanar with one or more of the first side S1 to the fourth side S4. For example, portions of the vertical part 330 disposed at the corner portions may be include an edge portion disposed coplanar with the first side S1 or the third side S3 (see FIG. 1A). In another example, each portion of the vertical part 330 disposed at a corner portion may be disposed to have an edge portion disposed coplanar with a respective one of the first side S1 to the fourth side S4 (see FIG. 4A).

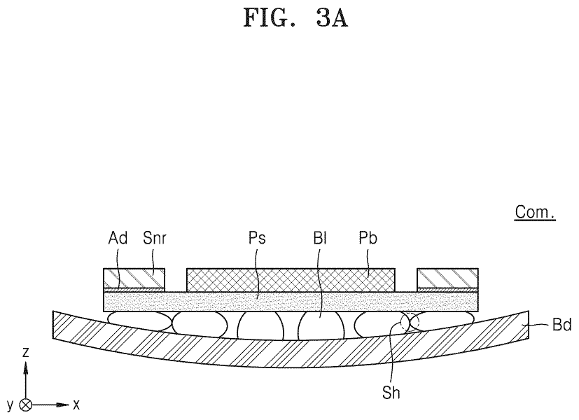

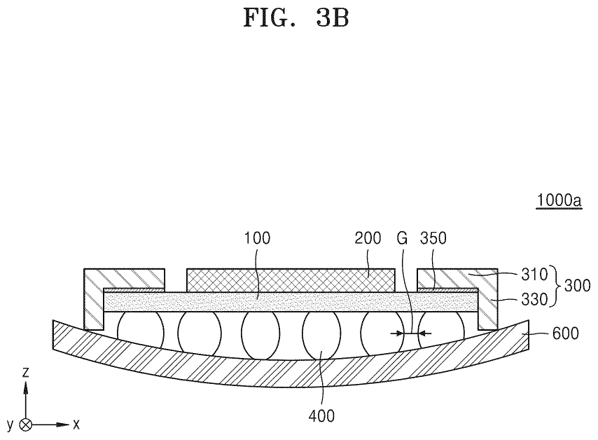

Furthermore, the vertical part 330 may protrude downward in the z direction from a lower surface of the package substrate 100. A first length L1 of a protrusion portion of the vertical part 330 may be within a range of about 39% to about 43% of a first height H1 of the external connection terminal 400. Here, the first height H1 of the external connection terminal 400 may be defined as a length up to a low point of the external connection terminal 400 downward in the z direction, with respect to the lower surface of the package substrate 100. The first length L1 of the protrusion portion of the vertical part 330 is not limited to the range above. For example, the first length L1 of the protrusion portion of the vertical part 330 may be appropriately set within a range for simultaneously preventing a non-wet error and a short-circuit error of the external connection terminal 400, based on warpage of the board (see board 600 of FIG. 2A) with the semiconductor package 1000 disposed thereon. The non-wet error and short-circuit error of the external connection terminal 400 will be described herein in more detail with reference to FIGS. 3A and 3B.

The stiffener 300 may include metal such as steel or Cu. A material of the stiffener 300 is not limited thereto. The stiffener 300 may be adhered and fixed to the package substrate 100 by an adhesive layer 350. For example, a lower surface of the horizontal part 310 of the stiffener 300 may be adhered and fixed to the upper surface of the package substrate 100 by the adhesive layer 350. The upper surface of the stiffener 300 may be lower than an upper surface of the package body 200. According to embodiments, the upper surface of the stiffener 300 may be substantially the same as the upper surface of the package body 200, or may be disposed higher than the upper surface of the package body 200.

The external connection terminal 400 may include, for example, a solder ball or a solder bump, or may include a pillar or a solder ball. The solder ball may have a spherical shape or a ball shape, and for example, may include tin (Sn), indium (In), bismuth (Bi), antimony (Sb), copper (Cu), silver (Ag), zinc (Zn), or lead (Pb), and/or an alloy thereof. The pillar may have a pillar shape such as a circular pillar or a tetragonal pillar (inclusive of an isometric pillar or an orthorhombic pillar). The pillar may include, for example, nickel (Ni), copper (Cu), palladium (Pd), platinum (Pt), or gold (Au), or an alloy thereof. A material of the solder ball and the pillar are not limited to the materials above. In the semiconductor package 1000 according to an embodiment, the external connection terminal 400 may be disposed in an array structure on the lower surface of the package substrate 100.

The external connection terminal 400 may have the first height H1 of about 500 μm or less. The external connection terminal 400 may have a pitch of about 1.0 mm or less. The first height H1 and pitch of the external connection terminal 400 are not limited to the numerical range above. For reference, an array structure of a solder ball or a substrate or a package including the array structure may be referred to as a ball grid array (BGA) structure, a BGA substrate, or a BGA package.

The passive device 500 may be provided in plurality on the upper surface of the package substrate 100. As illustrated in FIG. 1A, the passive device 500 may be disposed on the upper surface of the package substrate 100, and particularly, may be disposed on the upper surface of the package substrate 100, disposed inward from the stiffener 300, in a structure surrounding the package body 200. The passive device 500 may include, for example, one of an inductor, a resistor, or a capacitor. Furthermore, according to embodiments, the passive device 500 may be additionally disposed on the lower surface of the package substrate 100. In FIG. 1B, the passive device 500 is omitted from the illustration for convenience and ease of understanding. Similarly, the passive device 500 may be omitted from other cross-sectional views.

In the semiconductor package 1000 according to an embodiment, the stiffener 300 may be disposed at an outer portion of the package substrate 100 and may include the horizontal part 310 and the vertical part 330. Therefore, when the semiconductor package 1000 is mounted on the board (see board 600 of FIG. 2A) through the external connection terminal 400, the vertical part 330 of the stiffener 300 may prevent a short-circuit error of the external connection terminal 400 caused by the occurrence of warpage of the board 600. As a result, the semiconductor package 1000 according to an embodiment may include the stiffener 300 including the vertical part 330, and reliability of the semiconductor package 1000 may be improved.

FIGS. 2A, 2B, and 2C are respectively a plan view and cross-sectional views of a semiconductor package 1000a according to an embodiment. Descriptions which are the same as or similar to those provided with reference to FIGS. 1A, 1B, and 1C will be briefly given or may be omitted.

Referring to FIGS. 2A, 2B, and 2C, the semiconductor package 1000a according to an embodiment may further include a board 600. To provide a more detailed description, the semiconductor package 1000a according to an embodiment may include a package substrate 100, a package body 200, a stiffener 300, an external connection terminal 400, a passive device 500, and a board 600. The package substrate 100, the package body 200, the stiffener 300, the external connection terminal 400, and the passive device 500 may be the same as those described with reference to the semiconductor package 1000 of FIG. 1A. Hereinafter, the semiconductor package 1000 of FIG. 1A may be referred to as an upper package.

The board 600 may denote a substrate with an upper package mounted thereon. That is, the upper package may be mounted at a center portion of the board 600 by using the external connection terminal 400. Except for size, the board 600 may be similar to the package substrate 100 described above. For example, the size of the board 600 may be greater than 50*50 mm². In more detail, the size of the board 600 may be greater than or equal to 80*80 mm². The size of the board 600 is not limited to the numerical range above.

The board 600 may include a core layer, a wiring layer, and a protection layer. The core layer, the wiring layer, and the protection layer of the board 600 may be the same as those described with reference to the package substrate 100. In some embodiments, a thickness of each of the core layer, the wiring layer, and the protection layer of the board 600 may be greater than that of each of the core layer, the wiring layer, and the protection layer of the package substrate 100 corresponding thereto. In some embodiments, the number of layers of wiring lines of the wiring layer of the board 600 may be greater than the number of layers of wiring lines of the wiring layer of the package substrate 100. Furthermore, in some embodiments, the passive device 500 may be disposed on each of an upper surface and a lower surface of the board 600.

The stiffener 300 may surround an outer portion of the package substrate 100 and may have a structure including a vertical part 330, and thus, as illustrated in FIG. 2B, a lower surface of the vertical part 330 may be apart from the board 600, or as illustrated in FIG. 2C, the lower surface of the vertical part 330 may contact the upper surface of the board 600. To provide a more detailed description, in the board 600 where warpage slightly occurs as in FIG. 2B, the board 600 and the package substrate 100 may have a first center distance Dc1 at a center portion in an x direction, and the board 600 and the package substrate 100 may have a first edge distance De1 at outer portions in the x direction. In a board 600a where warpage occurs as in FIG. 2C, the board 600a and the package substrate 100 may have a second center distance Dc2 at a center portion in an x direction, and the board 600a and the package substrate 100 may have a second edge distance De2 at outer portions in the x direction.

For reference, when the upper package is stacked on the board 600 or 600a through external connection terminal 400, warpage of the board 600 or 600a may mainly occur in a reflow process. That is, when a high temperature of about 250° C. or more is applied in the reflow process, warpage may occur due to a temperature gradient. The warpage may be exasperated by the thickness of the board 600 or 600a, where a larger and thicker board is more likely to experience warpage, where a temperature gradient through the thickness of the board may be larger.

Furthermore, warpage of the board 600 or 600a may be determined as the difference between a portion disposed away from the package substrate 100 (e.g., a portion disposed farthest away from the package substrate 100) and a portion disposed toward the package substrate 100 (e.g., a portion disposed nearest to the package substrate 100) in a z direction, first warpage of the board 600 of FIG. 2B may be calculated as ‘Dc1−De1’ and second warpage of the board 600a of FIG. 2C may be calculated as ‘Dc2−De2’. As seen in FIGS. 2B and 2C, the second warpage may be greater than the first warpage. As in FIG. 2C, when warpage occurs in the board 600a, the vertical part 330 of the stiffener 300 may contact an upper surface of the board 600a at the outer portions in the x direction and may mechanically support the board 600a to maintain a certain distance between the package substrate 100 and the board 600a. Therefore, a short-circuit error may be prevented even when warpage of the board 600a occurs largely. A short-circuit error caused by warpage of the board 600a will be described herein in more detail with reference to FIGS. 3A and 3B.

FIGS. 3A and 3B are cross-sectional views of a semiconductor package of a comparative example and the semiconductor package of FIG. 2A.

Referring to FIG. 3A, in the semiconductor package (Com.) of the comparative example, a package body Pb may be mounted on a package substrate Ps, and a stiffener Snr may be adhered and fixed to an outer portion of the package substrate Ps in a tetragonal ring shape by using an adhesive layer Ad. An external connection terminal B1 may be disposed on a lower surface of the package substrate Ps, and the package substrate Ps and the package body Pb and the stiffener Snr thereon may be mounted on a board Bd by using the external connection terminal B1. Furthermore, in the semiconductor package (Com.) of the comparative example, the stiffener Snr may be disposed on only an upper surface of the package substrate Ps. Therefore, as illustrated in FIG. 3A, in a reflow process, when warpage occurs in the board Bd in an x direction, a short-circuit error Sh may occur where external connection terminals B1 disposed at end portions in the x direction may be crushed, and thus, may be connected with an external connection terminal B1 just adjacent thereto.

Referring to FIG. 3B, in the semiconductor package 1000a according to an embodiment, the stiffener 300 may include the horizontal part 310 and the vertical part 330. Accordingly, as illustrated in FIG. 3B, in a reflow process, when warpage occurs in a board Bd in an x direction, the vertical part 330 of the stiffener 300 may maintain an interval between the package substrate 100 and the board 600 at end portions in the x direction. For example, the vertical part 330 of the stiffener 300 may maintain, by a first length L1, the interval between the package substrate 100 and the board 600. As a result, a gap G may be maintained between adjacent external connection terminals 400. The gap G maintained between adjacent external connection terminals 400 may prevent a short-circuit error.

For example, in a conventional semiconductor package such as the semiconductor package (Com.) of the comparative example, when warpage of a board occurs by about 200 μm or more, a short-circuit error may occur. On the other hand, in the semiconductor package 1000a according to an embodiment, a short-circuit error may not occur even when warpage of about 300 μm or more occurs in the board 600.

For reference, when the first length L1 of the protrusion portion of the vertical part 330 of the stiffener 300 increases, a distance between the package substrate 100 and the board 600 may increase at a center portion of the board 600 in the x direction. In an example with a large first length L1, a non-wet error where the external connection terminal 400 is detached from the package substrate 100 or the board 600 may occur. Accordingly, the short-circuit error and the non-wet error may be prevented at the same time by appropriately adjusting the first length L1 of the protrusion portion of the vertical part 330 of the stiffener 300. For example, in the semiconductor package 1000a according to an embodiment, the first length L1 of the protrusion portion of the vertical part 330 of the stiffener 300 may be set to a range about 39% to about 43% of the first height H1 of the external connection terminal 400, so as to prevent the short-circuit error and the non-wet error at the same time.

FIGS. 4A, 4B, and 4C are plan views of a semiconductor package according to embodiments. FIGS. 4A, 4B, and 4C will be described with reference to FIGS. 1A, 1B, and 1C, and descriptions which are the same as or similar to those provided with reference to FIGS. 1A, 1B, and 1C, FIGS. 2A, 2B, and 2C, and FIGS. 3A and to 3B will be briefly given or may be omitted.

Referring to FIG. 4A, a semiconductor package 1000b according to an embodiment may be similar to the semiconductor package 1000a of FIG. 1A but may differ in arrangement position of a vertical part 330a of a stiffener 300a. In detail, in the semiconductor package 1000b according to an embodiment, the stiffener 300a may be disposed at an outer portion of a package substrate 100 and may include a horizontal part 310 and the vertical part 330a. The horizontal part 310 may cover upper surfaces of four side portions of the package substrate 100 having a tetragonal shape. For example, the horizontal part 310 may have a tetragonal ring shape surrounding an upper surface of an outer portion of the package substrate 100.

When sides of the package substrate 100 include a first side S1, a second side S2, a third side S3, and a fourth side S4 in a clockwise direction, the vertical part 330a may be disposed at an end of each of the first side S1 to the fourth side S4. In detail, the vertical part 330a may be disposed at a right end portion in an x direction at the first side S1, disposed at a lower end portion in a y direction at the second side S2, disposed at a left end portion in the x direction at the third side S3, and disposed at an upper end portion in the y direction at the fourth side S4. The vertical part 330a may be disposed at a portion corresponding to opposite ends of the package substrate 100 in the x direction. Here, the x direction may be a direction in which warpage occurs in a board (see board 600 of FIG. 2A) with the semiconductor package 1000b mounted thereon.

Referring to FIG. 4B, a semiconductor package 1000c according to an embodiment may be similar to the semiconductor package 1000a of FIG. 1A but may differ in arrangement positions and number of vertical parts 330b of a stiffener 300b. In detail, in the semiconductor package 1000c according to an embodiment, the stiffener 300b may be disposed at an outer portion of a package substrate 100 and may include a horizontal part 310 and the vertical part 330b. The horizontal part 310 may cover upper surfaces of side portions of the package substrate 100 having a tetragonal shape. For example, the horizontal part 310 may have a tetragonal ring shape surrounding an upper surface of an outer portion of the package substrate 100.

When the sides of the package substrate 100 include the first side S1, the second side S2, the third side S3, and the fourth side S4 in a clockwise direction, three vertical parts 330b may be disposed at each of the second side S2 and the fourth side S4. In detail, the vertical part 330b may be disposed at each of end portions and a center portion disposed along the y direction at the second side S2 and may be disposed at each of end portions and a center portion disposed along in the y direction at the fourth side S4. The vertical part 330b may be disposed at a portion corresponding to opposite end portions of the package substrate 100 in the x direction.

Referring to FIG. 4C, a semiconductor package 1000d according to an embodiment may be similar to the semiconductor package 1000a of FIG. 1A but may differ in structure of a vertical part 330c of a stiffener 300c. In detail, in the semiconductor package 1000d according to an embodiment, the stiffener 300c may be disposed at an outer portion of a package substrate 100 and may include a horizontal part 310 and the vertical part 330c. The horizontal part 310 may be disposed on upper surfaces of side portions of the package substrate 100 having a tetragonal shape. For example, the horizontal part 310 may have a tetragonal ring shape surrounding an upper surface of an outer portion of the package substrate 100.

When the sides of the package substrate 100 include the first side S1 to the fourth side S4 in a clockwise direction, a vertical part 330c may be disposed at each of the second side S2 and the fourth side S4, and may entirely cover the second side S2 and the fourth side S4. In detail, the vertical part 330c may extend in a y direction at the second side S2 and may entirely cover the second side S2. The vertical part 330c may extend in a y direction at the fourth side S4 and may entirely cover the fourth side S4. In FIG. 4C, each of the second side S2 and the fourth side S4 may be illustrated by a dashed line, and the horizontal part 310 and the vertical part 330c of the stiffener 300c may be differentiated from each other with respect to the dashed line. The vertical part 330c may be disposed at a portion corresponding to each of end portions of the package substrate 100 in an x direction.

FIGS. 5A and 5B are cross-sectional views illustrating a package body portion in the semiconductor package of FIG. 1B. FIGS. 5A and 5B will be described with reference to FIGS. 1A, 1B, and 1C, and descriptions which are the same as or similar to those provided with reference to FIGS. 1A, 1B, and 1C, FIGS. 2A, 2B, and 2C, FIGS. 3A and 3B, and FIGS. 4A, 4B, and 4C will be briefly given or may be omitted.

Referring to FIG. 5A, a semiconductor package 1000e according to an embodiment may have a package structure where a package body 200a includes a chip stack portion 220 on which a plurality of semiconductor chips may be stacked. In detail, similar to the semiconductor package 1000 of FIG. 1A, the semiconductor package 1000e according to an embodiment may include a package substrate 100, a package body 200a, a stiffener 300, an external connection terminal 400, and a passive device 500. The package substrate 100, the stiffener 300, the external connection terminal 400, and the passive device 500 may be the same as those described with reference to the semiconductor package 1000 of FIGS. 1A, 1B, and 1C. A structure of the stiffener 300 is not limited to a structure of the stiffener 300 of the semiconductor package 1000 of FIG. 1A and may have a structure of each of the stiffeners 300a to 300c of the semiconductor packages 1000b to 1000d of FIGS. 4A, 4B, and 4C.

The package body 200a may include a body substrate 210, a chip stack portion 220, a sealant 230, and a body connection terminal 240. The body substrate 210 may include, for example, silicon, glass, ceramic, or plastic. The body substrate 210 may include a plurality of single-layer or multi-layer wiring lines. The body connection terminal 240 may be disposed on a lower surface of the body substrate 210.

The chip stack portion 220 may be stacked on the body substrate 210 and may be electrically connected with the body substrate 210 through a wire 225. In detail, a first semiconductor chip CH1 may be stacked on the body substrate 210 through an adhesive layer 217, and a second semiconductor chip CH2 may be stacked on the first semiconductor chip CH1 through the adhesive layer 217. In this manner, four semiconductor chips may be stacked on the body substrate 210. The four semiconductor chips may include the first semiconductor chip CH1, a second semiconductor chip CH2, a third semiconductor chip CH3, and a fourth semiconductor chip CH4. The first to fourth semiconductor chips CH1 to CH4 may be connected with the body substrate 210 through the wire 225.

The chip stack portion 220 may include the first to fourth semiconductor chips CH1 to CH4. The number of semiconductor chips included in the chip stack portion 220 is not limited to four. For example, the chip stack portion 220 may include two, three, or five or more semiconductor chips. As illustrated in FIG. 5A, in the chip stack portion 220, the first to fourth semiconductor chips CH1 to CH4 may be stacked in a staircase structure. According to embodiments, the first to fourth semiconductor chips CH1 to CH4 may be stacked in a zigzag structure.

In the semiconductor package 1000e according to an embodiment, each chip of the first to fourth semiconductor chips CH1 to CH4 of the chip stack portion 220 may include a memory chip. For example, each of the first to fourth semiconductor chips CH1 to CH4 may include a dynamic random access memory (DRAM) chip. The chips of the first to fourth semiconductor chips CH1 to CH4 is not limited to the memory chip or the DRAM chip.

The sealant 230 may cover the chip stack portion 220 to protect the first to fourth semiconductor chips CH1 to CH4. The sealant 230 may cover an upper surface of the body substrate 210 and the wire 225 together. The sealant 230 may include, for example, a silicone-based material, thermo-curable resin, thermoplastic resin, or an ultraviolet (UV) curing material.

Referring to FIG. 5B, a semiconductor package 1000f according to an embodiment may have a package structure where a package body 200b includes a chip stack portion 220a on which a plurality of semiconductor chips are stacked. In detail, similar to the semiconductor package 1000 of FIG. 1A, the semiconductor package 1000f according to an embodiment may include a package substrate 100, a package body 200b, a stiffener 300, an external connection terminal 400, and a passive device 500. The package substrate 100, the stiffener 300, the external connection terminal 400, and the passive device 500 may be the same as those described with reference to the semiconductor package 1000 of FIGS. 1A, 1B, and 1C.

The package body 200a may include a body substrate 210, a chip stack portion 220a, a sealant 230, and a body connection terminal 240. The body substrate 210, the sealant 230, and the body connection terminal 240 may be the same as those described with reference to the package body 200a of the semiconductor package 1000e of FIG. 5A.

The chip stack portion 220a may be mounted on the body substrate 210 and may be electrically connected with the body substrate 210 through a through via 223 and a micro-bump 213. The chip stack portion 220a may include the first to fourth semiconductor chips CH1 to CH4. The number of semiconductor chips included in the chip stack portion 220a is not limited to four. For example, the chip stack portion 220a may include two, three, five or more semiconductor chips.

Each of the semiconductor chips (for example, the first to fourth semiconductor chips CH1 to CH4) of the chip stack portion 220a may be stacked on the body substrate 210 and a semiconductor chip thereunder by using the micro-bump 213 and an adhesive layer 217. Each of the first to third semiconductor chips CH1 to CH3 of the chip stack portion 220a may include a through via 223. Here, the through via 223 may pass through Si of the semiconductor chip and may thus be referred to as a through silicon via (TSV). Furthermore, the fourth semiconductor chip CH4 of an uppermost portion may not include a through via.

In the semiconductor package 1000f according to an embodiment, each of the first to fourth semiconductor chips CH1 to CH4 of the chip stack portion 220a may include a memory chip. For example, each of the first to fourth semiconductor chips CH1 to CH4 may include a DRAM chip. The first to fourth semiconductor chips CH1 to CH4 are not limited to the memory chip or the DRAM chip, and may be implemented as a different type of chip. Different chips of the first to fourth semiconductor chips CH1 to CH4 may be provided as different types of chips.

In some embodiments, the package body 200b may be a high bandwidth memory (HBM) package. When the package body 200b is an HBM package, the body substrate 210 may be replaced with a buffer chip, and the first to fourth semiconductor chips CH1 to CH4 may be stacked on the buffer chip. Here, the buffer chip may include a through via and a logic device. The buffer chip may be referred to as a logic chip or a control chip. In the HBM package, memory chips disposed on the buffer chip may be referred to as core chips. For example, the first to fourth semiconductor chips CH1 to CH4 may correspond to core chips. The buffer chip may be disposed under the core chips, and moreover, may integrate signals from the core chips to transfer integrated signals to the outside and may transfer a signal and power, received from the outside, to the core chips.

FIGS. 6A and 6B are cross-sectional views illustrating the package body portion in the semiconductor package of FIG. 1B. FIGS. 6A and 6B will be described with reference to FIGS. 1A, 1B, and 1C, and descriptions which are the same as or similar to those provided with reference to FIGS. 1A, 1B, and 1C, FIGS. 2A, 2B, and 2C, FIGS. 3A and 3B, FIGS. 4A, 4B, and 4C, and FIGS. 5A and 5B will be briefly given or may omitted.

Referring to FIG. 6A, a semiconductor package 1000g according to an embodiment may have a package structure where a package body 200c includes a chip stack portion 220b on which a plurality of semiconductor chips are stacked. In detail, similar to the semiconductor package 1000 of FIG. 1A, the semiconductor package 1000g according to an embodiment may include a package substrate 100, the package body 200c, a stiffener 300, an external connection terminal 400, and a passive device 500. The package substrate 100, the stiffener 300, the external connection terminal 400, and the passive device 500 may be the same as those described with reference to the semiconductor package 1000 of FIGS. 1A, 1B, and 1C.

The package body 200c may include a silicon (Si) interposer 210a, a chip stack portion 220b, a sealant 230, a body connection terminal 240a, and a semiconductor chip 250. The sealant 230 and the body connection terminal 240a may be the same as those described with reference to the package body 200a of the semiconductor package 1000e of FIG. 5A.

The Si interposer 210a may include a substrate 211, a through via 219, and a wiring layer 215. The chip stack portion 220b and the semiconductor chip 250 may be stacked on the package substrate 100 by using the Si interposer 210a. The Si interposer 210a may electrically connect the chip stack portion 220b and the semiconductor chip 250 with the package substrate 100. The Si interposer 210a may electrically connect the chip stack portion 220b with the semiconductor chip 250.

The substrate 211 of the Si interposer 210a may include, for example, Si. The through via 219 may pass through the substrate 211 and may extend. The substrate 211 may include Si, and thus, the through via 219 may correspond to a TSV. The through via 219 may extend to the wiring layer 215 and may be electrically connected with wirings of the wiring layer 215. According to an embodiment, the Si interposer 210a may include only a wiring layer and may not include a through via.

The body connection terminal 240a may be disposed on a lower surface of the Si interposer 210a. The Si interposer 210a may be stacked on the substrate 100 through the body connection terminal 240a. The Si interposer 210a may be used for converting an electrical signal between the semiconductor chip 250 and the chip stack portion 220b, or may be used for transferring the electrical signal. Therefore, the Si interposer 210a may not include devices such as an active device or a passive device.

A chip stack portion 220b may be disposed at sides of the semiconductor chip 250. For example, two chip stack portions 220b may be provided on opposite sides of the semiconductor chip 250. The number of chip stack portions 220b is not limited to two. For example, in some embodiments, a chip stack portion 220b may be disposed at a side of the semiconductor chip 250, or two chip stack portions 220b may be disposed at a given of the semiconductor chip 250. For example, four chip stack portions 220b may be provided, with two of the four chip stack portions 220b disposed on each of two sides of the semiconductor chip 250.

The chip stack portion 220b may have a structure similar to that of the package body 200b of the semiconductor package 1000f of FIG. 5B. For example, the chip stack portion 220b may be, for example, an HBM package. In more detail, a first chip stack portion 220-1 of the chip stack portion 220b may include a buffer chip 222B and a plurality of core chips 222C on the buffer chip 222B, and the buffer chip 222B and the core chips 222C may include a through via 223. Furthermore, an uppermost core chip 222C of the core chips 222C may not include the through via 223.

The chip stack portion 220b may be stacked on the Si interposer 210a through a micro-bump 213 on a lower surface of the buffer chip 222B. The core chips 222C on the buffer chip 222B may be sealed by an internal sealant 226. The internal sealant 226 may correspond to the sealant 230 in the package body 200b of the semiconductor package 1000f of FIG. 5B.

The semiconductor chip 250 may be disposed at a center portion of the Si interposer 210a. The semiconductor chip 250 may be a logic chip. Therefore, the semiconductor chip 250 may include a plurality of logic devices. The logic devices may include, for example, devices such as an AND gate, a NAND gate, an OR gate, a NOR gate, an exclusive OR (XOR) gate, an exclusive NOR (NOR) gate, an inverter (INV), an adder (ADD), a delay (DLY), a filter (FIL), a multiplexer (MXT/MXIT), an OR/AND/inverter (OAI), an AND/OR (AO) gate, an AND/OR/inverter (AOI), a D flip-flop, a reset flip-flop, a master-slave flip-flop, a latch, a counter, or a buffer. The logic devices may perform various signal processing such as analog signal processing, analog-to-digital (A/D) conversion, and control. The semiconductor chip 250 may be referred to as a graphics processing unit (GPU) chip, a central processing unit (CPU) chip, a system on glass (SOG) chip, a microprocessor unit (MPU) chip, an AP chip, or a control chip based on a function thereof.

The sealant 230 may cover the chip stack portion 220b and the semiconductor chip 250 on the Si interposer 210a. As illustrated in FIG. 6A, the sealant 230 may not cover an upper surface of each of the chip stack portion 220b and the semiconductor chip 250. In some embodiments, the sealant 230 may cover the upper surface of at least one of the chip stack portion 220b or the semiconductor chip 250.

For example, a structure of the semiconductor package 1000g according to an embodiment may be referred to as a 2.5-dimensional (2.5D) package structure. The 2.5D package structure may be a relative concept of a three-dimensional (3D) package structure where all semiconductor chips are stacked in a vertical direction and there is no Si interposer.

Referring to FIG. 6B, a semiconductor package 1000h according to an embodiment may include a Si bridge chip 260 instead of a Si interposer. In detail, similar to the semiconductor package 1000 of FIG. 1A, the semiconductor package 1000h according to an embodiment may include a package substrate 100a, a package body 200d, a stiffener 300, an external connection terminal 400, and a passive device 500. The stiffener 300, the external connection terminal 400, and the passive device 500 may be the same as those described with reference to the semiconductor package 1000 of FIGS. 1A, 1B, and 1C. In the package substrate 100a, a cavity CA may be formed in a center portion thereof and the Si bridge chip 260 may be inserted and disposed therein.

The package body 200d may include a chip stack portion 220b, a sealant 230, a semiconductor chip 250, and the Si bridge chip 260. The chip stack portion 220b and the sealant 230 may be the same as those described with reference to the package body 200a of the semiconductor package 1000e of FIG. 5A, and the semiconductor chip 250 may be the same as those described with reference to the package body 200c of the semiconductor package 1000g of FIG. 6A. As illustrated in FIG. 6B, a chip stack portion 220b may be disposed adjacent to the semiconductor chip 250. In some embodiments, two or more chip stack portions 220b may be disposed in a structure where the chip stack portions 220b are connected with the semiconductor chip 2250 through the Si bridge chip 260.

The Si bridge chip 260 may be disposed in a structure where the Si bridge chip 260 may be inserted into the cavity CA formed in a center portion of the package substrate 100a. The Si bridge chip 260 may connect the chip stack portion 220b with the semiconductor chip 250, each of which may be disposed on the package substrate 100. The Si bridge chip 260 may include a Si body and wiring lines. In some embodiments, the Si bridge chip 260 may include a through via which passes through the Si body.

Furthermore, the package substrate 100a may have a structure where the package substrate 100a includes a glass core substrate and a redistribution substrate, instead of a PCB. To provide a more detailed description, the glass core substrate of the package substrate 100a may include a cavity in a center portion thereof and may include a glass body at a periphery of the cavity. The Si bridge chip 260 may be disposed in the cavity. A plurality of through vias may be disposed in a glass body of the glass core substrate. The redistribution substrate may be disposed on a lower surface of each of the glass core substrate and the Si bridge chip 260. For reference, the redistribution substrate may be formed by placing a multi-layer wiring lines while building up ABF resin on the lower surface of each of the glass core substrate and the Si bridge chip 260.

In some embodiments, the redistribution substrate may be disposed on an upper surface of each of the glass core substrate and the Si bridge chip 260. That is, the glass core substrate and the Si bridge chip 260 may be connected with the chip stack portion 220b and the semiconductor chip 250 through the redistribution substrate.

Furthermore, in some embodiments, an insulation core substrate instead of the glass core substrate may be provided. For example, the insulation core substrate may include an insulation layer and wiring lines, and the wiring lines may have a multi-layer structure. The insulation layer of the insulation core substrate may include thermo-curable resin such as epoxy resin or a thermoplastic resin such as polyimide and may further include an inorganic filler. The insulation layer of the insulation core substrate may include, for example, prepreg, ABF, FR-4, or BT resin.

For reference, a structure of the semiconductor package 1000h according to an embodiment may be referred to as a 2.3-dimensional (2.3D) package structure. The 2.3D package structure may have a structure where the Si bridge chip 260 having a small size is inserted into the package substrate 100a and may thus have a difference with the 2.5D package structure where the Si interposer is disposed on the package substrate 100.

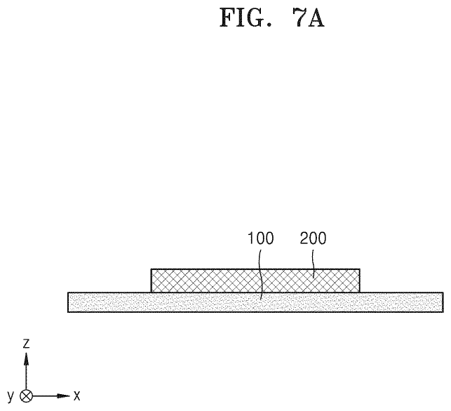

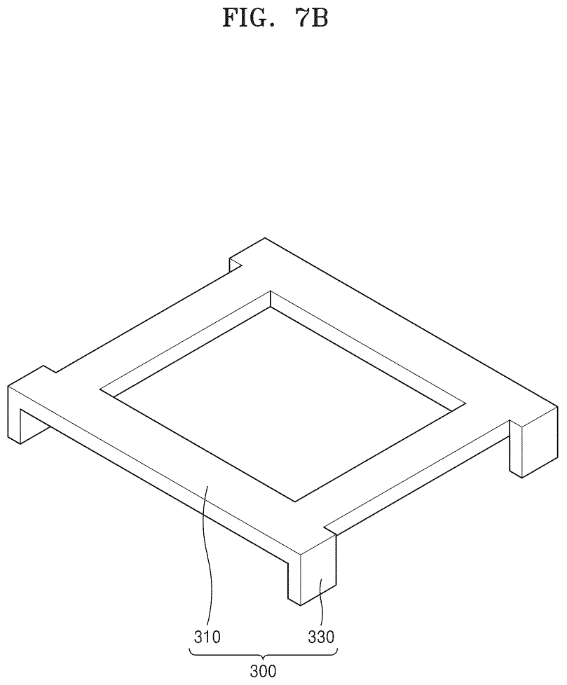

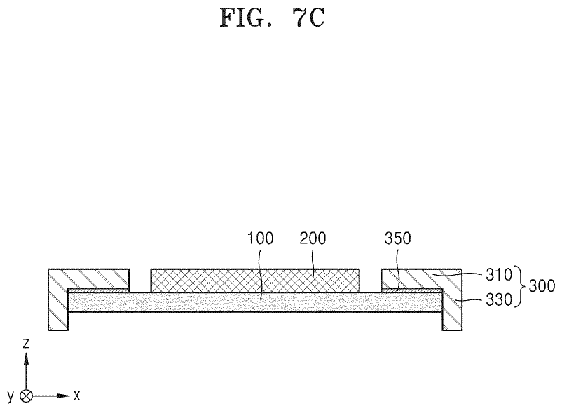

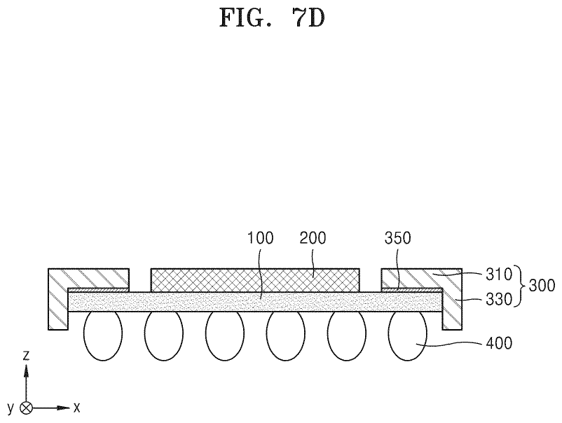

FIGS. 7A, 7B, 7C, and 7D are cross-sectional views simply illustrating a method of manufacturing a semiconductor package, according to an embodiment. FIGS. 7A, 7B, 7C, and 7D will be described with reference to FIGS. 1A, 1B, and 1C, and descriptions which are the same as or similar to those provided with reference to FIGS. 1A to 6B will be briefly given or may be omitted.

Referring to FIG. 7A, in the method of manufacturing a semiconductor package according to an embodiment, a package body 200 may be first mounted on a package substrate 100. The package body 200 may be mounted on the package substrate 100 through a body connection terminal such as a bump or a solder ball. The package body 200 may include a single semiconductor chip. The inventive concept is not limited thereto, and the package body 200 may have a package structure including a chip stack portion. For example, as illustrated in FIGS. 5A and 5B, and FIGS. 6A, and 6B, package bodies 200a to 200d having the package structure may be mounted on package substrates 100 and 100a.

Referring to FIG. 7B, a stiffener 300 may be prepared. The stiffener 300 may include a horizontal part 310 and a vertical part 330. The horizontal part 310 may have a tetragonal ring shape. The vertical part 330 may have a shape which extends downward in a z direction from the horizontal part 310. As illustrated in FIG. 7B, the vertical part 330 may be disposed at end portions in a y direction, at the second side and the fourth side of the horizontal part 310 extending in the y direction. A structure of the vertical part 330 of the stiffener 300 is not limited thereto. For example, as illustrated in FIGS. 4A, 4B, and 4C, the vertical part 330 of the stiffener 300 may have various structures.

An operation of preparing the stiffener 300 may be performed before an operation of mounting the package body 200 on the package substrate 100. The operation of preparing the stiffener 300 may be performed simultaneously with the operation of mounting the package body 200 on the package substrate 100.

Referring to FIG. 7C, after the stiffener 300 is prepared, the stiffener 300 may be coupled to the package substrate 100. That is, the stiffener 300 may be adhered and fixed to an upper surface of an outer portion of the package substrate 100 by using an adhesive layer 350. After the stiffener 300 is coupled to the package substrate 100, the vertical part 330 of the stiffener 300 may protrude downward in the z direction at a lower surface of the package substrate 100.

Referring to FIG. 7D, subsequently, an external connection terminal 400 may be attached on the lower surface of the package substrate 100. A height of the external connection terminal 400 may be constant. As described herein, a length of a protrusion portion of the vertical part 330 of the stiffener 300 may have a range of about 39% to about 43% of a height of the external connection terminal 400. The semiconductor package 1000 of FIG. 1A may be manufactured through the attachment of the external connection terminal 400. Subsequently, as the semiconductor package 1000 is mounted on a board 600 through the external connection terminal 400, the semiconductor package 1000a of FIG. 2A may be manufactured. In a reflow process of the semiconductor package 1000a of FIG. 2A, the vertical part 330 of the stiffener 300 may maintain a certain interval between the package substrate 100 and the board 600, and thus, a short-circuit error between adjacent external connection terminals 400 may be prevented, thereby implementing a semiconductor package having reliability.

Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a package body disposed on an upper surface of the package substrate; and
a stiffener disposed at sides of the package substrate,
wherein the stiffener comprises a horizontal part disposed on the upper surface of the package substrate at the sides of the package substrate and a vertical part extending downward from the horizontal part in a vertical direction substantially perpendicular to the upper surface of the package substrate at corners of the package substrate, and
the vertical part protrudes in the vertical direction from a lower surface of the package substrate.

2. The semiconductor package of claim 1, wherein the sides of the package substrate include a first side and a third side opposite to each other and extend in a first direction substantially parallel to the upper surface of the package substrate, and
a second side and a fourth side opposite to each other and extend in a second direction substantially perpendicular to the first direction and substantially parallel to the upper surface of the package substrate.

3. The semiconductor package of claim 2, wherein the vertical part is disposed at end portions of each of the second side and the fourth side of the package substrate in the second direction.

4. The semiconductor package of claim 2, wherein the vertical part is disposed at each corner of the package substrate formed between the first side, the second side, the third side, and the fourth side of the package substrate, and on the first side, the second side, the third side, and the fourth side of the package substrate.

5. The semiconductor package of claim 2, wherein the vertical part is disposed at a center portion of each of the second side and the fourth side of the package substrate.

6. The semiconductor package of claim 2, wherein the vertical part is disposed at end portions of each of the second side and the fourth side of the package substrate in the second direction and at center portions of each of the second side and the fourth side of the package substrate.

7. The semiconductor package of claim 1, further comprising an external connection terminal disposed on the lower surface of the package substrate,
wherein a first length of the vertical part in the vertical direction from the lower surface of the package substrate is within a range of about 39% to about 43% of a height of the external connection terminal, and
the height of the external connection terminal is a length downward from the lower surface of the package substrate in the vertical direction.

8. The semiconductor package of claim 1, further comprising an external connection terminal disposed on a lower surface of the package substrate,
the package substrate is mounted on a board of an external electronic device through the external connection terminal, and
a lower surface of the vertical part contacts an upper surface of an outer portion of the board.

9. The semiconductor package of claim 1, wherein the package body comprises a single semiconductor chip, or a chip stack portion having a structure where a plurality of semiconductor chips are stacked.

10. The semiconductor package of claim 1, further comprising a passive device disposed on the package substrate between the package body and the stiffener.

11. A semiconductor package comprising:
a package substrate having a tetragonal shape;
a package body disposed on an upper surface of the package substrate;
a stiffener disposed at sides of the package substrate; and
an external connection terminal disposed on a lower surface of the package substrate,
wherein a first side and a third side of the package substrate are opposite to each other and extend in a first direction parallel to the upper surface of the package substrate,
a second side and a fourth side of the package substrate are opposite to each other and extend in a second direction perpendicular to the first direction and parallel to the upper surface of the package substrate,
the stiffener comprises a horizontal part disposed on the upper surface of the package substrate at the sides of the package substrate and a plurality of vertical parts extending downward from the horizontal part in a vertical direction perpendicular to the upper surface of the package substrate at corners of the package substrate formed by the first side, the second side, the third side, and the fourth side, and
the plurality of vertical parts protrude from the lower surface of the package substrate in the vertical direction and a protrusion length of the plurality of vertical parts has a range of about 39% to about 43% of a height of the external connection terminal with respect to the lower surface of the package substrate.

12. The semiconductor package of claim 11, wherein the plurality of vertical parts are disposed at end portions of each of the second side and the fourth side of the package substrate in the second direction.

13. The semiconductor package of claim 11, wherein the plurality of vertical parts are disposed at the first side, the second side, the third side, and the fourth side of the package substrate.

14. The semiconductor package of claim 11, wherein the plurality of vertical parts extend in the second direction at the second side and the fourth side of the package substrate.

15. The semiconductor package of claim 11, wherein the package body comprises a single semiconductor chip or a chip stack portion having a structure where a plurality of semiconductor chips are stacked.

16. A semiconductor package comprising:
an external board;
a package substrate disposed on the external board and having a tetragonal shape including four sides;
a package body disposed at a center portion of an upper surface of the package substrate;
a stiffener disposed at each of the four sides of the package substrate; and
an external connection terminal disposed between a lower surface of the package substrate and the external board,
wherein a first side and a third side of the four sides of the package substrate are opposite to each other and extend in a first direction parallel to the upper surface of the package substrate,
a second side and a fourth side of the four sides of the package substrate are opposite to each other and extend in a second direction perpendicular to the first direction and parallel to the upper surface of the package substrate,
the stiffener comprises a horizontal part disposed on the upper surface of the package substrate at the four sides of the package substrate and a vertical part extending downward from the horizontal part in a vertical direction perpendicular to the upper surface of the package substrate at four corners of the package substrate,
the external board has a warpage shape where a center portion is disposed away from the package substrate in the first direction, and
the vertical part protrudes by a first length in the vertical direction from a lower surface of the package substrate and contacts an upper surface of the external board in the first direction.

17. The semiconductor package of claim 16, wherein the first length is within a range of about 39% to about 43% of a height of the external connection terminal.

18. The semiconductor package of claim 16, wherein the vertical part is disposed at end portions of each of the second side and the fourth side of the package substrate in the second direction, or is disposed at each corner of the package substrate formed between the first side, the second side, the third side, and the fourth side of the package substrate, and on the first side, the second side, the third side, and the fourth side of the package substrate.

19. The semiconductor package of claim 16, wherein the vertical part extends in the second direction at each of the second side and the fourth side of the package substrate and contacts an upper surface of the external board at four sides thereof.

20. The semiconductor package of claim 16, wherein the package body comprises a single semiconductor chip or a chip stack portion has a structure where a plurality of semiconductor chips are stacked.
